(19) United States
(12) Patent Application Publication
(10) Pub. No.: US 2004/0123194 A1
(43) Pub. Date: Jun. 24, 2004

(54) Systems and methods for testing tri-state bus drivers

(76) Inventors: John G. Rohrbaugh, Ft. Collins, CO (US); Jeff Rearick, Ft. Collins, CO (US)

Correspondence Address: AGILENT TECHNOLOGIES, INC., Legal Department, DL429, Intellectual Property Administration, P.O. Box 7599, Fort Collins, CO, 80537-0599, US

(21) Appl. No.: 10/327,517

(22) Filed: Dec. 20, 2002

(51) Int. Cl. G01R 31/28

(52) U.S. Cl. 714/724

(57) ABSTRACT

Methods for testing tri-state bus drivers of a tri-state bus are provided. One such a method can be summarized by: selecting a tri-state bus to be tested; and performing a tri-state test including at least one of a driver speed test procedure and a driver static test procedure, the driver speed test procedure including at least one of testing the selected tri-state bus for an enable line driver slow-to-turn-on condition and an enable line driver slow-to-turn-off condition, the driver static test procedure including at least one of testing the selected tri-state bus for an enable line driver stuck-on condition and an enable line driver stuck-off condition. Systems and other methods also are provided.

### BACKGROUND OF THE INVENTION

### FIELD OF THE INVENTION

The present invention generally relates to testing of tri-state logic and, more particularly, to systems and methods for testing tri-state drivers and associated circuitry.

### DISCUSSION OF THE RELATED ART

Integrated circuits (ICs) are electrical circuits composed of transistors, resistors, capacitors, and other components on a single semiconductor “chip” in which the components are interconnected to perform a variety of functions. Typical examples of ICs include, for example, microprocessors, programmable logic devices (PLDs), electrically erasable programmable memory devices (EEPROMs), random access memory devices (RAMs), operational amplifiers and voltage regulators.

A circuit designer typically designs an IC by creating a circuit schematic indicating the electrical components and their interconnections. Often, designs are simulated by a computer to verify functionality and to ensure that performance goals are satisfied. While these designs can be simulated to verify functionality and performance goals, there are various shortcomings when completing actual testing. For instance, it is known that it is difficult to perform digital tests on circuitry that can behave non-digitally. Examples of circuitry that can behave non-digitally include tri-state devices, such as tri-state drivers.

In order to actually test an enable line of a tri-state driver, a value should be defined on the tri-state bus when all the drivers are off. This is because the normal default off values for a tri-state driver on the tri-state bus (i.e. an internal node) cannot be reliably propagated to an external chip pin. If there is no default value on the tri-state bus, the tri-state driver enable lines become untestable and a test may not discover bad parts. However, adding circuitry to define a value can slow the overall performance of the original circuit.

Additional circuitry to define a value can include putting a bus-keeper on the tri-state bus. Such a tri-state bus-keeper typically requires a two-step test, with a first step to initialize and the second step to test. This two-step test can be complicated. Additionally, the technique of putting a bus-keeper on the tri-state bus may compromise the circuit performance. Thus, tri-state circuitry is currently not fully testable, and therefore, the use of tri-state circuitry tends to be minimized or even avoided.

### SUMMARY OF THE INVENTION

Systems and methods for testing tri-state bus drivers of a tri-state bus are provided. In this regard, an embodiment of a method can be summarized by: selecting a tri-state bus to be tested; and performing a tri-state test including at least one of a driver speed test procedure and a driver static test procedure, the driver speed test procedure including at least one of testing the selected tri-state bus for an enable line driver slow-to-turn-on condition and an enable line driver slow-to-turn-off condition, the driver static test procedure including at least one of testing the selected tri-state bus for an enable line driver stuck-on condition and an enable line driver stuck-off condition.

An embodiment of a system comprises: a system for testing tri-state drivers of an integrated circuit, said system being operative to perform a tri-state test including at least one of a driver speed test procedure and a driver static test procedure, the driver speed test procedure including at least one of testing the tri-state bus for an enable line driver slow-to-turn-on condition and an enable line driver slow-to-turn-off condition, the driver static test procedure including at least one of testing the tri-state bus for an enable line driver stuck-on condition and an enable line driver stuck-off condition.

An embodiment of a system comprises: means for selecting a tri-state bus to be tested; and means for performing a tri-state test including at least one of a driver speed test procedure and a driver static test procedure, the driver speed test procedure including at least one of testing the selected tri-state bus for an enable line driver slow-to-turn-on condition and an enable line driver slow-to-turn-off condition, the driver static test procedure including at least one of testing the selected tri-state bus for an enable line driver stuck-on condition and an enable line driver stuck-off condition.

### DESCRIPTION OF THE DRAWINGS

The accompanying drawings incorporated in and forming a part of the specification illustrate several aspects of the present invention, and together with the description serve to explain the principles of the invention. In the drawings:

FIG. 1 is a schematic diagram illustrating one possible hardware implementation of driver analyzer circuitry utilized to test tri-state bus drivers on a chip.

FIG. 2 is a block diagram illustrating an alternative embodiment of the driver analyzer of FIG. 1, implemented in a computer-readable medium in a computer system.

FIG. 3 is a flow chart depicting one possible implementation of the driver analyzer used in conjunction with driver analyzer circuitry to test tri-state bus drivers as shown in FIGS. 1 and 2.

FIG. 4 is a flow chart illustrating one possible implementation of a driver speed test procedure utilized in the driver analyzer as shown in FIG. 3.

FIG. 5 is a flow chart illustrating one possible implementation of a diagnostic slow-to-turn-off test process as utilized in the driver speed procedure and driver analyzer as shown in FIGS. 1-4.

FIG. 6 is a flow chart illustrating one possible implementation of a production slow-to-turn-off test process as utilized in the driver speed procedure and driver analyzer as shown in FIGS. 1-4.

FIG. 7 is a flow chart illustrating one possible implementation of a slow-to-turn-on test process utilized in the driver speed procedure and driver analyzer as shown in FIGS. 1-4.

FIG. 8 is a flow chart illustrating one possible implementation of the driver static test procedure utilized in the driver analyzer as shown in FIGS. 1-3.

FIG. 9 is a flow chart illustrating one possible implementation of the diagnostic driver stuck-on test process utilized in the static test procedure and driver analyzer as shown in FIGS. 1-3 and 8.

FIG. 10 is a flow chart illustrating one possible implementation of the production driver stuck-on test process utilized in the static test procedure and driver analyzer as shown in FIGS. 1-3 and 8.

FIG. 11 is a flow chart illustrating one possible implementation of the driver stuck-off test process utilized in the static test procedure and driver analyzer as shown in FIGS. 1-3 and 8.

### DETAILED DESCRIPTION

Having summarized various aspects of the present invention, the invention will now be described in detail with reference to the drawings. While the invention will be described in connection with these drawings, there is no intent to limit it to the embodiments disclosed therein. On the contrary, the intent is to cover all alternatives, modifications and equivalents included within the spirit and scope of the invention as protected by the appended claims.

As will be described in detail, embodiments of driver analyzers of the present invention potentially enable testing of tri-state bus drivers with minimal impact to circuit performance. In some embodiments, circuitry is used to define an initial value on a tri-state bus. Field effect transistors (FETs) are used for pull-up and pull-down circuitry, which are controlled by test signals. During normal operation, the additional load of a trace of a wire to an open FET can be detected. This trace of a wire to an open FET has a very minor effect on the circuit, as compared to the typical capacitance of a tri-state bus and all its drivers. During a test mode, either the pull-up circuitry or the pull-down circuitry can be enabled to put a default value on the tri-state bus.

In alternative embodiments, a scannable latch can be added to the driver analyzer. This scannable latch can then be enabled during the test to simplify the task of observing the test results. The scannable latch can be connected to the tri-state bus and used to capture output from the tri-state bus.

In other alternative embodiments, two scannable registers can be added to driver analyzer circuitry such that their outputs control the pull-up circuitry and pull-down circuitry. In such an embodiment, a default value for each of the circuitry can be controlled independently. Note, it is preferable to power-up these registers such that the FETs of the circuitry would be off during normal operation of the tri-state bus circuit.

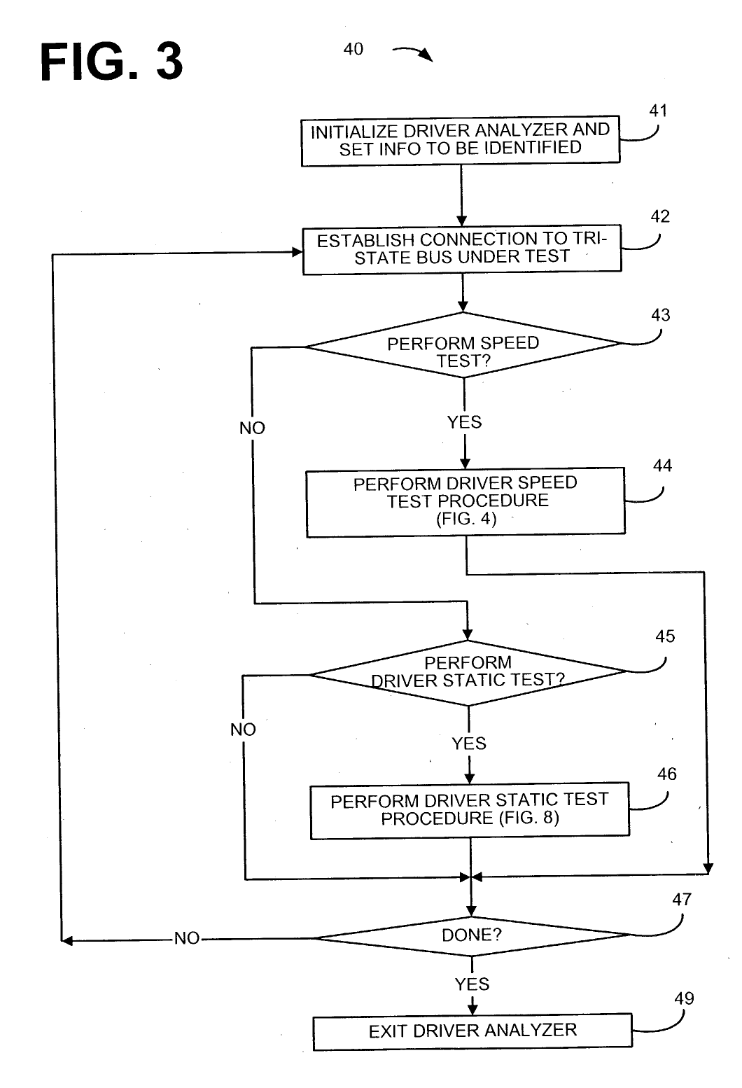

Typically, embodiments of the driver analyzer make passes through the driver circuitry on a tri-state bus in an attempt to identify problem tri-state driver circuits. In the first pass, the driver analyzer determines if there is to be a speed test procedure or a driver static test procedure. After determining which type of test procedure is to be performed, the driver analyzer then performs the selected test procedure. The driver speed test procedure can include, but is not limited to, diagnostic slow-to-turn-off test processes, production slow-to-turn-off test processes and slow-to-turn test processes. The driver static test procedure can include, but is not limited to, diagnostic driver stuck-on test processes, and driver stuck-off test processes. These individual types of test processes are herein defined in further detail with regard to FIGS. 3-11.

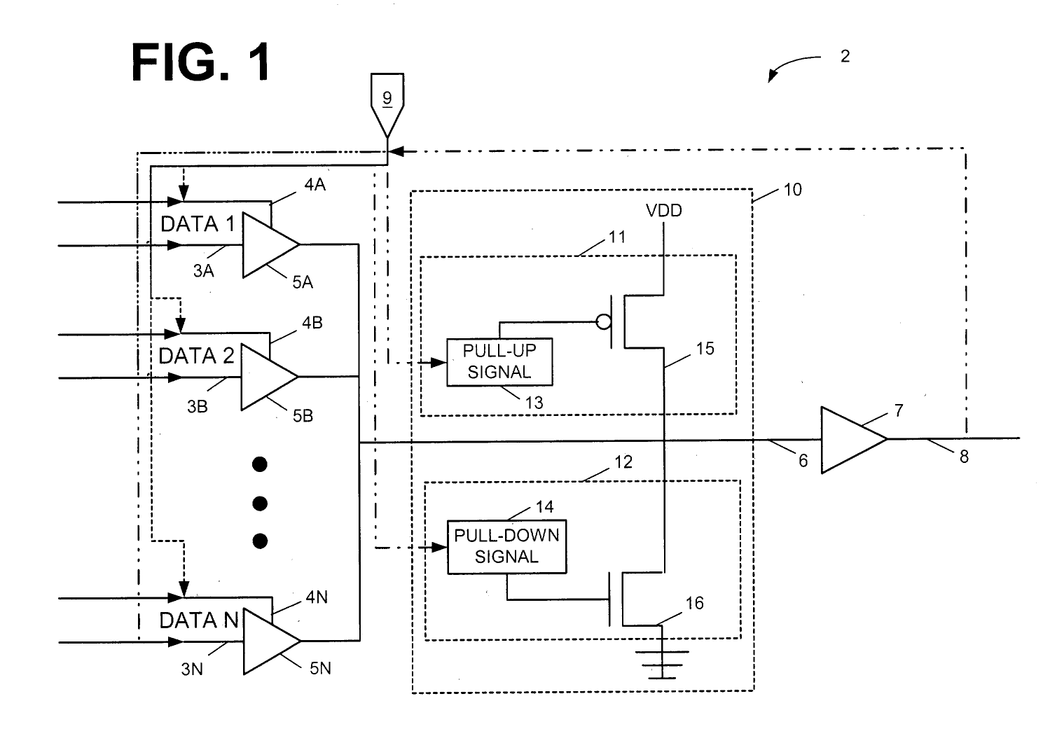

Illustrated in FIG. 1 is a schematic diagram of one possible hardware implementation of the system (driver analyzer circuitry) 10 on tri-state bus circuitry 2. Briefly, the driver analyzer circuitry 10 is comprised of pull-up circuitry 11 and pull-down circuitry 12, that are each connected to tri-state bus 6 and enable testing of the tri-state bus drivers 5 (A-N). Driver analyzer circuitry 10 also can optionally include a driver analyzer (not shown) for controlling the driver analyzer circuitry 10. Although FIG. 1 shows a buffer 7 between the tri-state bus 6 and the wire 8, which is connected to a port 9, it should be understood that a variety of circuitry may be present between the tri-state bus 6 and the port 9, given that a tri-state bus is an internal node (i.e. not a port) of an integrated circuit.

In the embodiment of FIG. 1, the driver analyzer circuitry 10, pull-up circuitry 11 and pull-down circuitry 12, tri-state bus 6 and tri-state bus drivers 5 (A-N) can be controlled and observed by a port 9. However, it should be understood that multiple ports may be used for control and observe purposes. The port 9 enables a driver analyzer to input control and data signals from a computer system outside of tri-state bus circuitry 2. Data signals can be input to tri-state bus drivers 5 (A-N) and control signals can be used to provide control of the tri-state bus drivers 5 (A-N), pull-up signal 13 and pull-down signal 14. These data and control signals determine the data which is placed onto the tri-state bus 6. The port 9 also enables the driver analyzer to receive data signals from the buffered bus output 8.

In some alternative embodiments, driver analyzer circuitry and/or an associated driver analyzer can be implemented in hardware on the chip (not shown) to be tested. In such a hardware embodiment, the driver analyzer circuitry and/or driver analyzer can be implemented with any one or a combination of the following technologies, which are each well known in the art: a discrete logic circuit(s) having logic gates for implementing logic functions upon data signals, an application specific integrated circuit(s) (ASIC) having appropriate combinational logic gates, a programmable gate array(s) (PGA), a field programmable gate array(s) (FPGA), etc.

In some embodiments, a scannable latch (not shown) can be added to the driver analyzer circuitry. This scannable latch can then be enabled during the test. This scanable latch should make the task of observing the test results simpler. The scanable latch can be used for output from the tri-state bus and would be connected to the tri-state bus.

In some embodiments, two scannable registers (not shown) can be added to the driver analyzer circuit such that their outputs control the pull-up and pull-down tri-state bus testing FETs. In such an embodiment, a default value for each FET can be controlled independently. Note, power-up of these registers should be accomplished such that the FETs would be off during normal operation of the tri-state bus circuit.

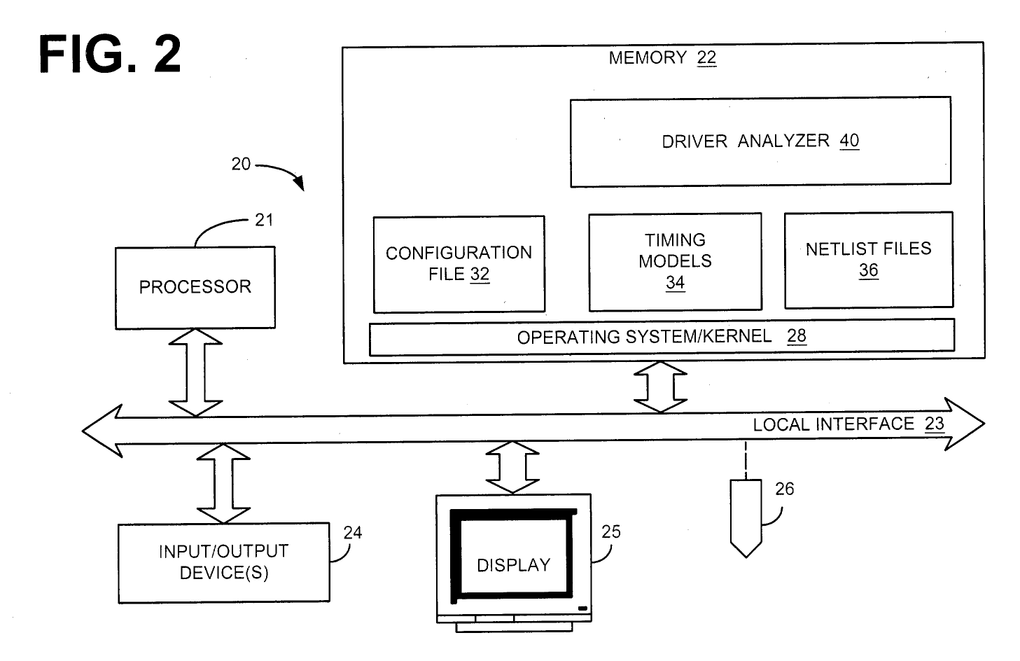

FIG. 2 is a block diagram illustrating an example of a driver analyzer 40 of the present invention, situated within a computer-readable medium, such as, for example, a memory in a general-purpose computer system 20. Generally, in terms of hardware architecture, as shown in FIG. 2, the computer system 20 includes a processor 21, memory 22, and one or more input devices and/or output (I/O) devices (or peripherals) that are communicatively coupled via a local interface 23. The local interface 23 can be, for example but not limited to, one or more buses or other wired or wireless connections, as is known in the art. The local interface 23 may have additional elements, which are omitted for simplicity, such as controllers, buffers (caches), drivers, repeaters, and receivers, to enable communications. Further, the local interface 23 may include address, control, and/or data connections to enable appropriate communications among the aforementioned components.

The processor 21 is a hardware device for executing software that can be stored in memory 22. The processor 21 can be virtually a custom made or commercially available processor, a central processing unit (CPU) or an auxiliary processor among several processors associated with the computer 20, and a semiconductor based microprocessor (in the form of a microchip) or a macroprocessor.

The memory 22 can include any one or combination of volatile memory elements (e.g., random access memory (RAM, such as DRAM, SRAM, etc.)) and nonvolatile memory elements (e.g., ROM, hard drive, tape, CDROM, etc.). Moreover, the memory 22 may incorporate electronic, magnetic, optical, and/or other types of storage media. Note that the memory 22 can have a distributed architecture, where various components are situated remote from one another, but can be accessed by the processor 21.

The software in memory 22 may include one or more separate programs, each of which comprises an ordered listing of executable instructions for implementing logical functions. In the example of FIG. 2, the software in the memory 12 includes an operating system 28, the driver analyzer 40, the configuration file 32, timing models 34, and the netlist file 36. The configuration file(s) 32 contains information that informs the driver analyzer 40 how to perform its analysis, and various numbers of configuration file(s) 32 may be used. The timing models file 34 contains information that informs the driver analyzer 40 of the various timing sequences of each particular tri-state bus driver 5 (A-N) components. The netlist file 36, as is well known, defines the various integrated circuit components, and their inter-relations.

The operating system 28 essentially controls the execution of other computer programs, such as the driver analyzer circuitry 10, and provides scheduling, input-output control, file and data management, memory management, and communication control and related services.

The I/O devices 24 may include input devices, for example but not limited to, a keyboard, mouse, scanner, microphone, etc. Furthermore, the I/O devices 14 may also include output devices, for example but not limited to, a printer, display 25, etc. Finally, the I/O devices 24 may further include devices that communicate both inputs and outputs, for instance but not limited to, a modulator/demodulator (modem; for accessing another device, system, or network), a radio frequency (RF) or other transceiver, a telephonic interface, a bridge, a router, etc. The computer system 20 includes chip interface 26 for use in accessing a chip. This chip interface 26 accesses pull-up circuitry 11, pull-down circuitry 12, tri-state bus 6 and tri-state bus drivers 5 (A-N), as shown in FIG. 1, using the port 9 (FIG. 1) in order to test operation on the tri-state bus drivers 5 (A-N).

If the computer 20 is a PC, workstation, or the like, the software in the memory 22 may further include a basic input output system (BIOS) (omitted for simplicity). The BIOS is a set of essential software routines that initialize and test hardware at startup, start the O/S 28, and support the transfer of data among the hardware devices. The BIOS is stored in ROM so that the BIOS can be executed when the computer 20 is activated.

When the computer 20 is in operation, the processor 11 is configured to execute software stored within the memory 22, to communicate data to and from the memory 22, and to generally control operations of the computer 20 pursuant to the software. The driver analyzer circuitry 10 of the present invention and the O/S 28 are read, in whole or in part, by the processor 21, perhaps buffered within the processor 21, and then executed.

When the driver analyzer 40 is implemented in software, as is shown in FIG. 2, it should be noted that can be stored on virtually any computer-readable medium for use by or in connection with any computer related system or method. In the context of this document, a computer-readable medium is an electronic, magnetic, optical, or other physical device or means that can contain or store a computer program for use by or in connection with a computer related system or method. The driver analyzer 40 of the present invention can be embodied in any computer-readable medium for use by or in connection with an instruction execution system, system, or device, such as a computer-based system, processor-containing system, or other system that can fetch the instructions from the instruction execution system, system, or device and execute the instructions.

In the context of this document, a “computer-readable medium” can be any means that can store, communicate, propagate, or transport the program for use by or in connection with the instruction execution system, system, or device. The computer readable medium can be, for example but not limited to, an electronic, magnetic, optical, electromagnetic, infrared, or semiconductor system, system, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory.

Illustrated in FIG. 3, is a flow chart depicting one possible implementation of the driver analyzer 40 used in conjunction with the driver analyzer circuitry 10 to test tri-state bus drivers 5 (A-N), as shown in FIGS. 1 and 2. The driver analyzer 40 can be performed in an on-chip or off-chip (FIG. 2) manner. Off-chip operation of the driver analyzer 40 can, for example, be performed using the port 9 (FIG. 1) to connect chip interface 26 (FIG. 2). In on-chip operation of the driver analyzer 40, the driver analyzer 40 would be located on-chip and include connections to the same elements connected to the port 9 (FIG. 1). The example implementation depicted in FIG. 3 shows the executions of speed and/or driver static test procedures. Both test procedures can be performed to test a data line 3A-N (FIG. 1) of the input of a tri-state driver 5A-N (FIG. 1).

First, the driver analyzer 40 is initialized and sets the information to be identified at step 41. The information set incorporates the identification of the tri-state bus to be tested, and includes but is not limited to, the specific bus, group of busses, or all the tri-state busses on the chip. At step 42, the driver analyzer 40 establishes the connection to the tri-state bus under test.

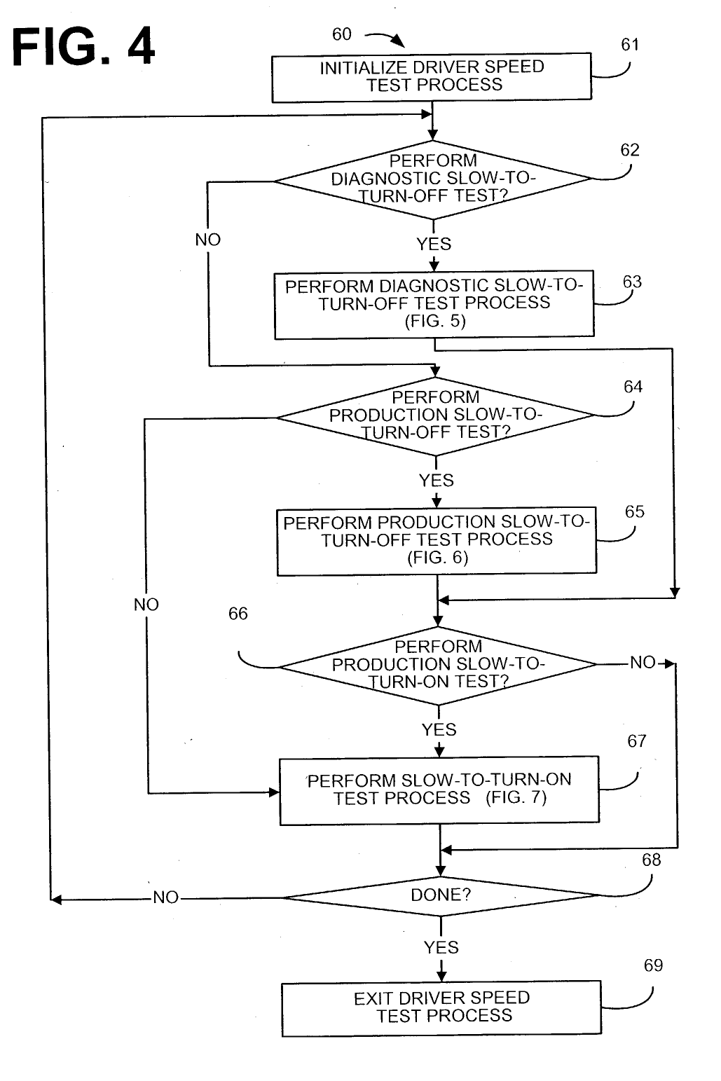

At step 43, the driver analyzer 40 then determines if the test processes to be performed are associated with the speed test procedure. If the driver analyzer 40 determines at step 43 that the driver speed test procedure is not to be performed, the driver analyzer 40 proceeds to step 45 to determine if the driver static test procedure is to be performed. However, if it is determined at step 43 that the speed test procedure is to be performed, the driver analyzer 40 performs the driver speed test procedure at step 44. The driver speed procedure includes, but is not limited to, test processes for enable line driver slow-to-turn-on and driver slow-to-turn-off conditions. The driver speed test procedure is herein defined in further detail with regard to FIG. 4.

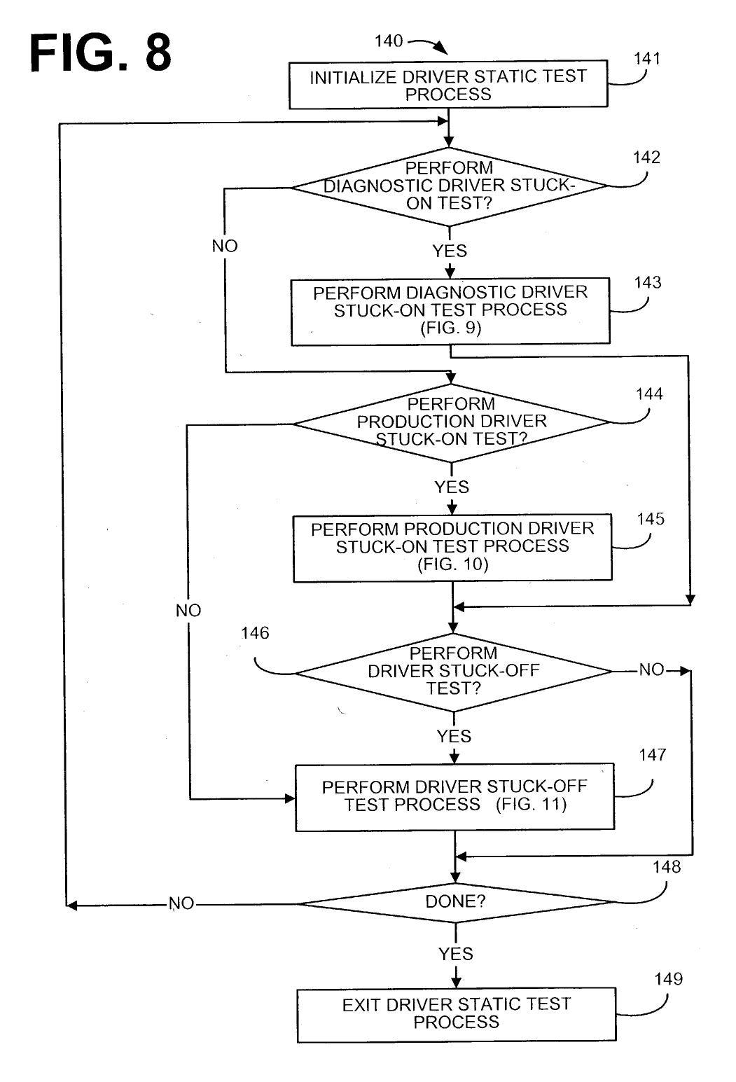

At step 45, the driver analyzer determines if the driver static test procedure is to be performed. If it is determined at step 45 that the driver static test procedure is not to be performed, the driver analyzer 40 proceeds to step 47 to determine if more tests are to be performed. However, if it is determined at step 45 that the driver static test procedure is to be performed, then the driver analyzer 40 performs the driver static test procedure at step 46. The driver static test procedure includes, but is not limited to, test processes for enable line stuck-on and stuck-off conditions. The driver static test procedure is herein defined in further detail with regard to FIG. 8.

At step 47, the driver analyzer determines if there are more tests to be performed. If it is determined that there are more tests to be performed, the driver analyzer 40 then returns to repeat steps 42-47. However, if it is determined at step 47 that there are no more tests to be performed, the driver analyzer 40 then exits at step 49.

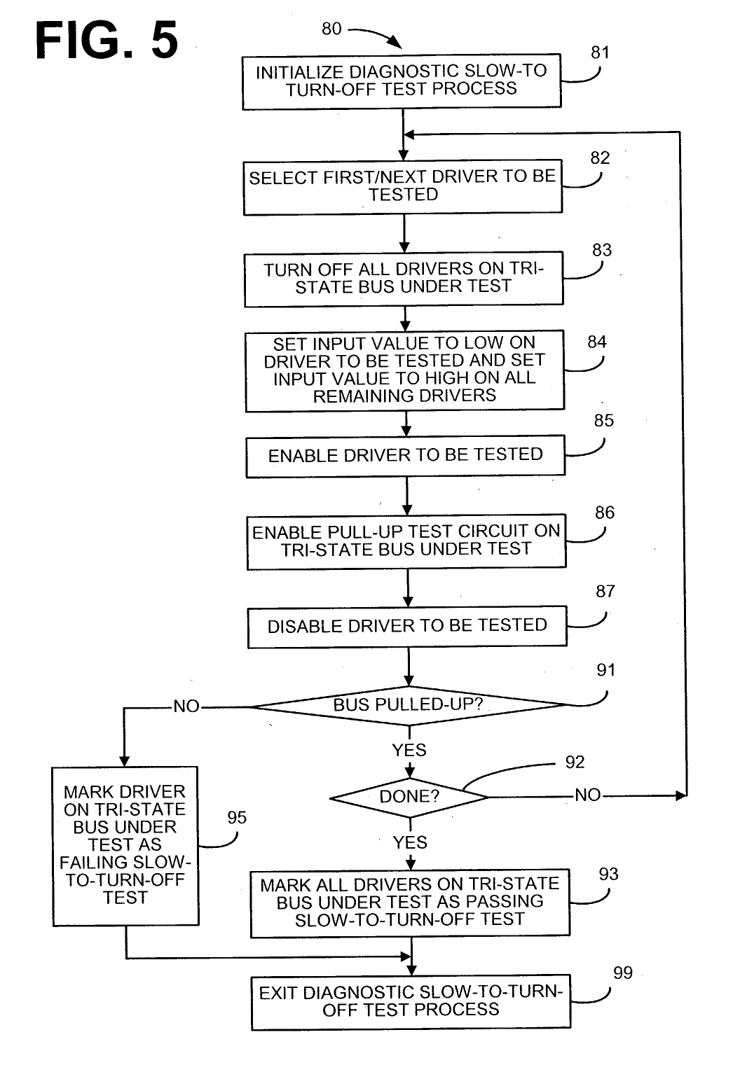

FIG. 4 is a flow chart illustrating an example of one possible implementation of a driver speed test process 60 utilized in the driver analyzer 40 of the present as shown in FIGS. 1-3. The driver speed test process enables a user to identify and perform a variety of speed test processes. These speed test processes include, but are not limited to, slow-to-turn-off and slow-to-turn-on test processes. These test processes will be defined in further detail with regard to FIGS. 5-7.

First the driver speed test process 60 is initialized at step 61. At step 62, it is determined if the diagnostic slow-to-turn-off test process is to be performed. If it is determined at step 62 that the diagnostic slow-to-turn-off test is not to be performed, then the driver speed test process 60 skips to step 64. However, if it is determined at step 62 that the diagnostic slow-to-turn-off test is to be performed, then the diagnostic slow-to-turn-off test process is performed at step 63. The diagnostic slow-to-turn-off test process is herein defined in further detail with regard to FIG. 5. After performing the diagnostic slow-to-turn-off test process at step 63, the driver slow-to-turn test process 60 skips to step 66 to determine if the slow-to-turn-on test process is to be performed.

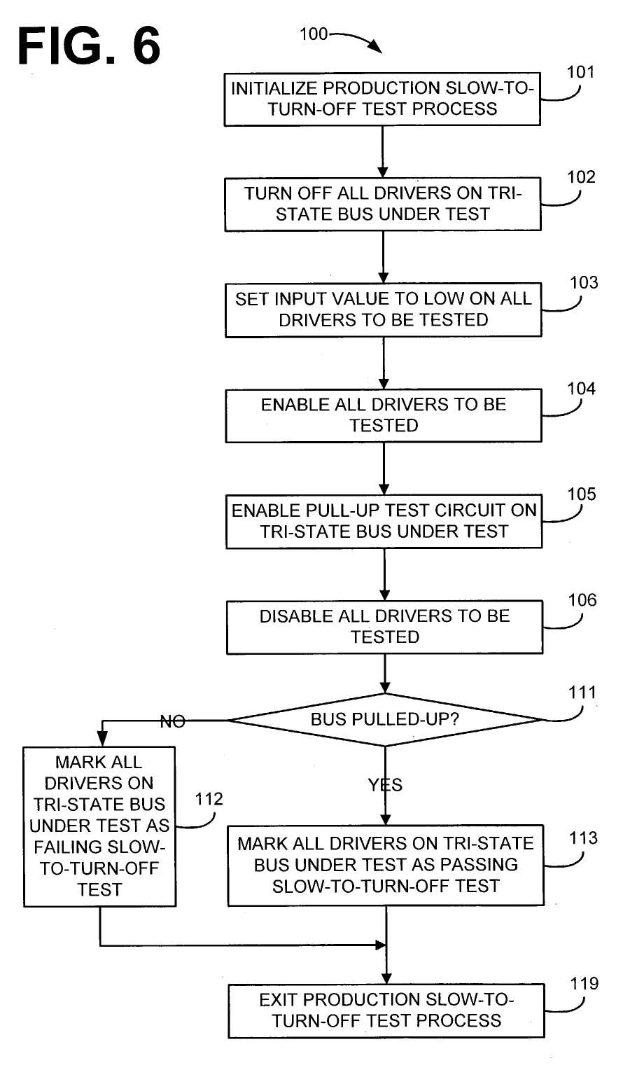

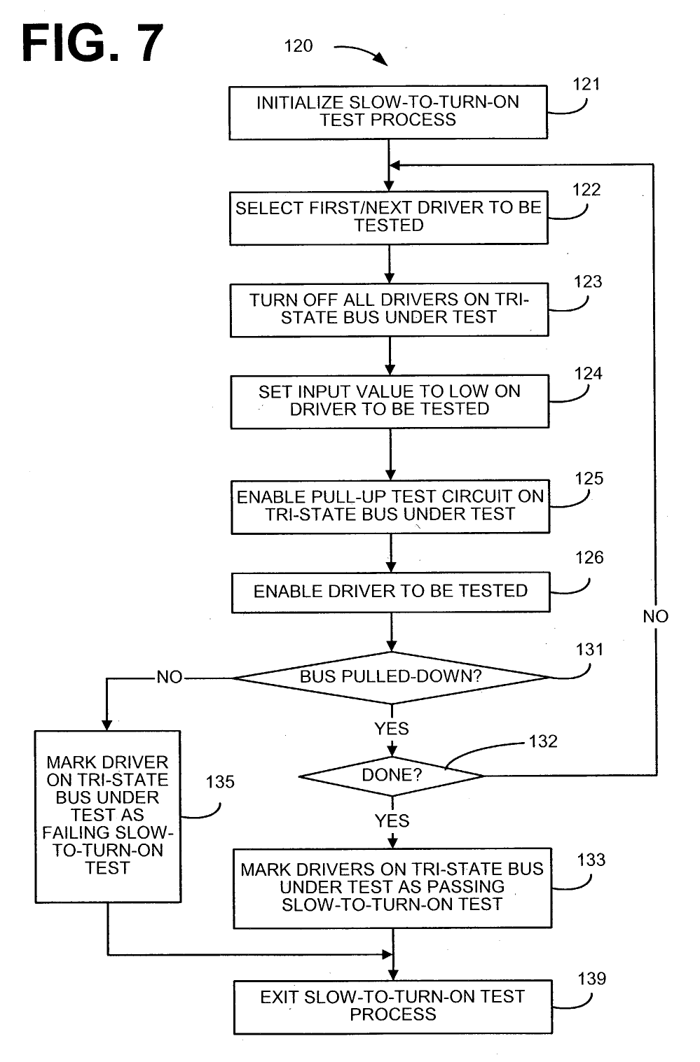

At step 64, it is determined if the production slow-to-turn-off test process is to be performed. If it is determined at step 64 that the production slow-to-turn-off test process is not to be performed, then the driver speed test process 60 skips to step 67 to perform the slow-to-turn-on test process. The slow-to-turn-on test process is herein defined in further detail with regard to FIG. 7. However, if it is determined at step 64 that the production slow-to-turn-off test process is to be performed, then the driver speed test process 60 performs the production slow-to-turn-off test process at step 65. The production slow-to-turn-off test process is herein defined in further detail with regard to FIG. 6.

At step 66, the driver speed test process 60 then determines if the production slow-to-turn-on test is to be performed at step 66. If it is determined at step 66 that the production slow-to-turn-on test process is not to be performed, then the driver speed test process 60 skips to step 68 to determine if there are more tests to be performed. However, if it is determined at step 66 that the production slow-to-turn-on test process is to be performed, then the slow-to-turn-on test process is performed at step 67. The slow-to-turn-on test process is herein defined in further detail with regard to FIG. 7.

At step 68, the driver slow-to-turn test process 60 determines if there are more test processes to be performed. If it is determined at step 68 that there are more tests to be performed, then the driver speed test process 60 returns to repeat steps 62-68. However, if it is determined at step 68 that there are no more driver speed test processes to be performed, then the driver speed test process 60 exits at step 69.

FIG. 5 is a flow chart illustrating an example of one possible implementation of a method of the diagnostic slow-to-turn-off test process 80 utilized in the driver speed test process 60 in the driver analyzer 40 of the present invention, as shown in FIGS. 1-4. The diagnostic test is characterized by slow execution, but does provide enough information to identify a failing driver enable line. The advantages of the diagnostic test process are to makes a slow-to-turn-off test of tri-state driver enable lines possible. It also enables the ability to identify the failing driver enable line with low impact to design performance and provides a simple fault observation.

First, the diagnostic slow-to-turn-off test process 80 is initialized at step 81. At step 82, the diagnostic slow-to-turn-off test process 80 selects the first/next driver to be tested. At step 83, all the drivers on the tri-state bus to be tested are turned off. At step 84, the input value is set to low on the driver to be tested. At step 85, the driver to be tested is enabled and at step 86, the test pull-up circuit on the tri-state bus under test is also enabled At step 87, the diagnostic slow-to-turn-off test process 80 disables the driver to be tested.

At step 91, the diagnostic slow-to-turn-off test process 80 then determines if the bus is still pulled-up. If it is determined that the bus at step 91 is still pulled-up, then the diagnostic slow-to-turn-off test process 80 proceeds to step 92 to determine if there are more drivers to be tested. If it is determined at step 92 that there are more drivers to be tested, then the diagnostic slow-to-turn-off test process 80 returns to repeat steps 82-91.

However, if it is determined at step 92 that all the drivers on the tri-state bus under test have been tested, then the diagnostic slow-to-turn-off test process 80 marks all the drivers on the tri-state bus under test as passing slow-to-turn-off test, then exits at step 99. However, if it is determined at step 91 that the bus is not still pulled-up, the diagnostic slow-to-turn-off test process 80 marks the driver on the tri-state bus as failing the slow-to-turn-off test at step 95, and then exits at step 99.

FIG. 6 is a flow chart illustrating an example of one possible implementation of a method of a production slow-to-turn-off test process 100 utilized in the speed test process 60 and driver analyzer 40 of the present invention, as shown in FIGS. 1-4. The production slow-to-turn-off test process 100 is characterized by rapid execution with a pass/fail result. However, the production slow-to-turn-off test 100 does not provide enough information to identify the failing driver enable line. The advantages of the production slow-to-turn-off test process 100 are that it makes the testing of tri-state driver enable lines possible for slow-to-turn-off test conditions and can rapidly determine a pass/fail result. The production slow-to-turn-off test process also utilizes the test circuitry and provides low impact on design performance and provides for simple fault observation.

First, the production slow-to-turn-off test process 100 is initialized at step 101. At step 102, all the drivers on the tri-state bus under test are turned off. At step 103, the input value is set to low on all drivers to be tested and all drivers to be tested are enabled at step 104. At step 105, the pull-up test circuitry on the tri-state bus under test is enabled. At step 106, the production slow-to-turn-off test process 100 then disables all the drivers to be tested.

At step 111, a determination is made as to whether the bus is still pulled-up. If it is determined at step 111 that the bus is still not pulled-up, then the production slow-to-turn-off test process 100 marks all the drivers on the on the tri-state bus as failing the slow-to-turn-off process, and then exits at step 119. However, if is determined at step 111 that the bus is still pulled-up, the production slow-to-turn-off test process 100 marks all the drivers on the tri-state bus under test as passing the slow-to-turn-off test, and then exits at step 119.

FIG. 7 is a flow chart illustrating an example of one possible implementation of a method of a slow-to-turn-on test process 120 utilized in the speed test process 60 and driver analyzer 40 of the present invention, as shown in FIGS. 1-4. The slow-to-turn-on test process is characterized by rapid execution, but does provide enough information to identify the failing driver enable line. The slow-to-turn-on test process makes it possible to test tri-state driver enable lines for slow to turn test conditions with minimal impact to design performance and simple fault observation.

First, the slow-to-turn-on test process is initialized at step 121. At step 122, the slow-to-turn-on test process 120 selects the first/next driver to be tested. At step 123, all the drivers on the tri-state bus under test are turned off and at step 124 an input value is set to low on the driver selected to be tested at step 122 above. At step 125, the test pull-up circuitry on the tri-state bus under test is enabled and at step 126, the driver to be tested is enabled.

At step 131, the slow-to-turn-on test process 120 determines if the bus is still pulled-down. If it is determined at step 131 that the bus is still not pulled-down, then the slow-to-turn-on test process 120 marks the driver on the tri-state bus under test as failing the slow-to-turn-on test at step 135, and exits at step 139.

However, if it is determined at step 131 that the bus is still pulled-down, then the slow-to-turn-on test process 120 determines if there are more drivers on the tri-state bus under test to be tested at step 132. If it is determined at step 132 that there are more drivers to be tested, the slow-to-turn-on test process 120 then returns to repeat steps 122-131.

Note, with respect to the processes depicted in FIGS. 5, 6 and 7, some of the functions depicted should be performed “at speed.” For instance, steps 87 and 91 (FIG. 5), steps 106 and 111 (FIG. 6) and steps 126 and 131 (FIG. 7) should be performed in rapid sequence. The greater the lapse in time, the less effective the test may become.

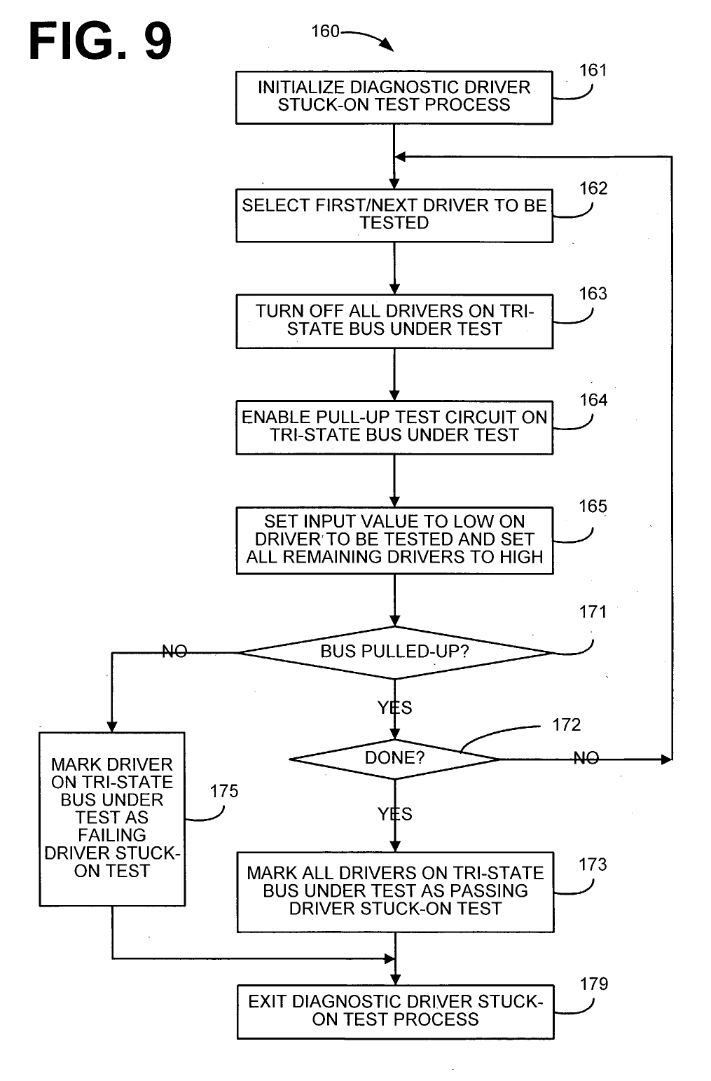

FIG. 8 is flow chart illustrating an example of one possible implementation of the driver static test procedure utilized in the driver analyzer 40 of the present invention as shown in FIGS. 1-3. The driver static test procedure enables a variety of different driver static tests to be performed. These driver static tests include, but are not limited to, diagnostic driver stuck-on tests, production driver stuck-on tests, and driver stuck-off test. Examples of these tests are herein described in further detail with regard to FIGS. 9-11.

First, the driver static test procedure 140 determines if the diagnostic driver stuck-on test is to be performed. If it is determined at step 142 that the diagnostic driver stuck-on test is not to be performed, the driver static test procedure 140 then skips to step 144. However, if it is determined at step 142 that the diagnostic driver stuck-on test is to be performed, then the diagnostic driver stuck-on test process is performed at step 143. The diagnostic driver stuck-on test process is herein described in further detail with regard to FIG. 9. After performing the diagnostic driver stuck-on test process at step 143, the driver static test procedure 140 then proceeds to step 146 to determine if the driver stuck-off test is to be performed.

At step 144, the driver static test procedure 140 determines if the production driver stuck-on test is to be performed. If it is determined at step 144 that the production driver stuck-on test is not to be performed, the driver static test procedure 140 then proceeds to step 147 to perform the driver stuck-off test process. However, if it is determined at step 144 that the production driver stuck-on test is to be performed, then the driver static procedure 140 performs the production driver stuck-on test process at step 145. The production driver stuck-on test process is herein defined in further detail with regard to FIG. 100

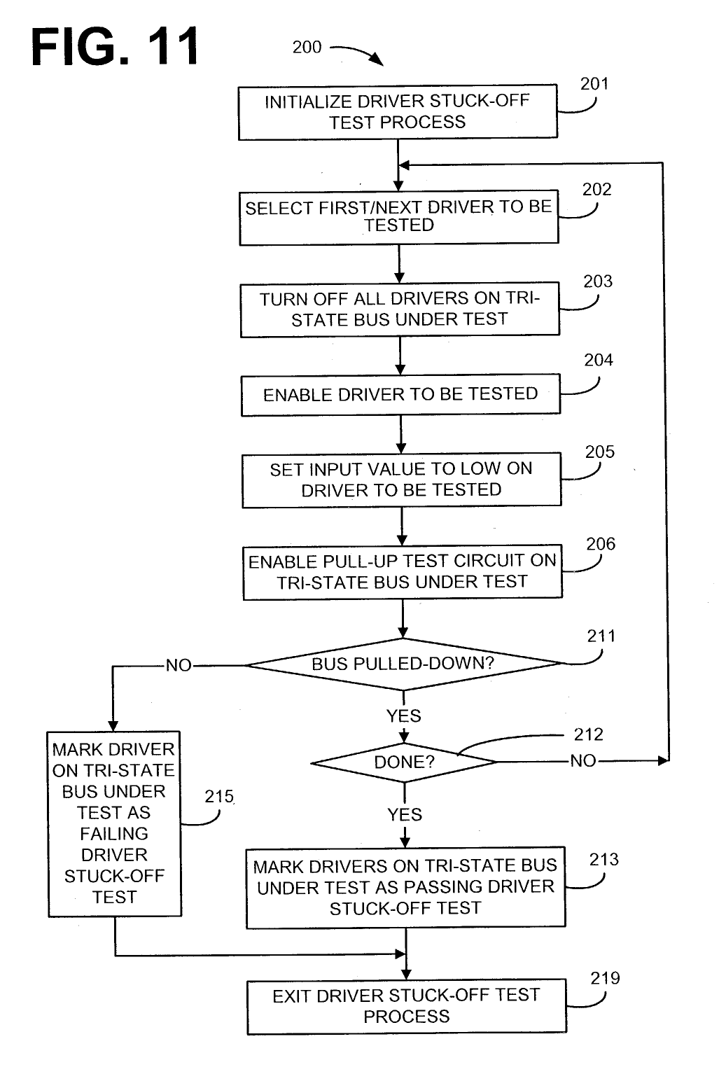

At step 146, the driver static test procedure 140 determines if the driver stuck-off test is to be performed. If it is determined at step 146 that the driver stuck-off test process is not to be performed, then the driver static test procedure 140 then skips to step 148. However, if it is determined at step 146 that the driver stuck-off test is to be performed, then the driver static test procedure 140 performs the driver stuck-off test process at step 147. The driver stuck-off test process is herein defined in further detail with regard to FIG. 11.

At step 148, the driver static test procedure 140 determines if there are more tests to be performed. If it is determined at step 148 that there are more tests to be performed, then the driver static test procedure 140 returns to repeat steps 142-148. However, if it is determined at step 148 that there are no more tests to be performed, then the driver static test procedure exits at step 149.

FIG. 9 is a flow chart illustrating an example of one possible implementation of a method of a diagnostic driver stuck-on test process 160 utilized by the driver stuck-on test procedure 140 utilized in the driver analyzer 40 of the present invention as shown in FIGS. 1-3 and 8. The diagnostic driver stuck-on test process is characterized by slower execution, but provides enough information to identify a failing driver enable line. One advantage of the diagnostic driver stuck-on test process is that it makes possible the task of enable lines for a stuck-on condition. The diagnostic driver stuck-on test process enables the identification of the failing driver enable line with a low impact on design performance and while still providing simple fault observation.

First, the diagnostic driver stuck-on test process 160 is initialized at step 161. At step 162 the diagnostic driver stuck-on test process 160 selects the first/next driver to be tested. At step 163, all the drivers on the tri-state bus under test are turned off. At step 164, the pull-up test circuitry on the tri-state bus under test is enabled and at step 165 an input value is set to low on the driver to be tested and input values are set to high for all remaining drivers.

At step 171, the diagnostic driver stuck-on test process 160 determines if the bus is pulled-up. If it is determined at step 171 that the bus is not pulled-up, the diagnostic driver stuck-on test process 160 marks the driver on the tri-state bus as failing the driver stuck-on test at step 175, and then exits at step 179. However, if it is determined at step 171 that the bus is pulled-up, then the diagnostic driver stuck-on test process 160 determines if there are more drivers to be tested at step 172. If it is determined at step 172 that there are more drivers to be tested, then the diagnostic driver stuck-on test process 160 returns to repeat steps 162-171. However, if it is determined at step 172 that there are no more test drivers on the bus under test to be tested, then the diagnostic driver stuck-on test process 160 marks all the drivers on the tri-state bus under test as passing the driver stuck-on test at step 173, and exits at step 179.

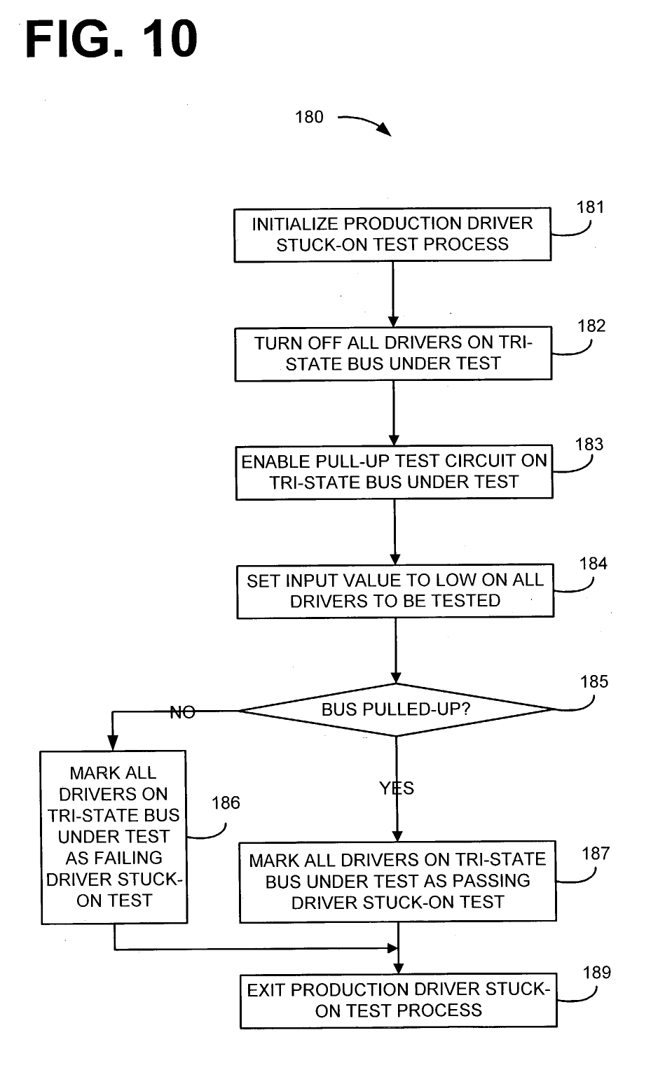

FIG. 10 is a flow chart illustrating an example of one possible implementation of a method of a production driver stuck-on test process 180 utilized by the driver stuck-on test procedure 140 and driver analyzer 40 of the present invention as shown in FIGS. 1-3 and FIG. 8. The production testing of tri-state drivers is characterized by rapid execution with a pass/fail result, but does not provide enough information to identify the failing driver enable line stuck on. One advantage for the production driver stuck-on test method is that it makes possible the testing of tri-state driver enable lines for stuck on conditions and rapidly can provide pass/fail results. Advantages also can include low impact on design performance of the tri-state bus circuitry with simple fault observation.

First, the production driver stuck-on test process 180 is initialized at step 181. At step 182, all the drivers on the tri-state bus under test are turned off. At step 183, the pull-up test circuitry on the tri-state bus under test is enabled and an input value is set to low on all drivers to be tested at step 184.

At step 185, the production driver stuck-on test process 180 determines if the bus is pulled-up. If it is determined at step 185 that the bus is not pulled-up, the production driver stuck-on test process 180 marks all the drivers on the tri-state under test as failing the driver stuck-on test, and then exits at step 189. However, if it is determined at step 185 that the bus is still pulled-up, then the production driver stuck-on test process 180 marks off the drivers on the tri-state bus under test as passing the production driver stuck-on test, and then exits at step 189.

FIG. 11 is a flow chart illustrating an example of one possible implementation of a method of a driver stuck-on test process 200 utilized by the driver static test process 140 and driver analyzer 40 of the present invention as shown in FIGS. 1-3 and FIG. 8. The driver stuck-off test makes possible the testing of tri-state driver enable lines for possible stuck-off conditions. This includes the low impact on design performance of the tri-state bus driver with simple fault observation characteristics.

First, the driver stuck-off test process 200 is initialized at step 201. At step 202, the driver stuck-off process test process selects the first/next driver to be tested. At step 203, all the drivers on the tri-state bus under test are turned off and at step 204 the driver to be tested at step 202 is enabled. At step 205, an input value is set to low on the driver selected to be tested at step 202. At step 206, the pull-up test circuitry on the tri-state bus driver under test is enabled.

At step 211, the driver stuck-off test process 200 then determines if the bus is still pulled-up. If it is determined at step 211 that the bus is not still pulled-up, then the driver stuck-off test process 200 marks the driver on the tri-state bus under test as failing the driver stuck-off test process at step 215, and then exits at step 219. However, if it is determined at step 211 that the bus is still pulled-up, the driver stuck-off test process 200 then determines if there are more drivers on the tri-state bus under test to be tested.

If it is determined at step 212 that there are more drivers on the tri-state bus under test to be tested, the driver stuck-off test process 200 then returns to repeat steps 202-211. However, if it is determined at step 212 that there are no more drivers to be tested on the tri-state bus under test, the driver stuck-off test process 200 marks all drivers on the tri-state bus under test as passing the driver stuck-off test at step 213, and then exits at step 219.

The foregoing description is not intended to be exhaustive or to limit the invention to the precise forms disclosed. Obvious modifications or variations are possible in light of the above teachings. In this regard, the embodiments discussed were chosen and described to provide illustration of the principles of the invention and its practical application to thereby enable one of ordinary skill in the art to utilize the invention in various embodiments and with various modifications as are suited to the particular use contemplated. For example, the speed tests have been shown and described herein as setting an input value low and setting a corresponding pull-up. Clearly, setting an input value high and setting a corresponding pull-down also could be used.

All such modifications and variations are within the scope of the invention as determined by the appended claims when interpreted in accordance with the breadth to which they are fairly and legally entitled.

What is claimed:

1. A method for testing tri-state bus drivers of a tri-state bus in an integrated circuit comprising:
selecting a tri-state bus to be tested; and
performing a tri-state test including at least one of a driver speed test procedure and a driver static test procedure, the driver speed test procedure including at least one of testing the selected tri-state bus for an enable line driver slow-to-turn-on condition and an enable line driver slow-to-turn-off condition, the driver static test procedure including at least one of testing the selected tri-state bus for an enable line driver stuck-on condition and an enable line driver stuck-off condition.

2. The method of claim 1, wherein the driver speed test procedure comprises:
selecting a first driver to be tested;
turning off all drivers on the tri-state bus;
setting an input value to low on the driver to be tested; and
enabling a pull-up test circuit on the tri-state bus.

3. The method of claim 2, wherein the driver speed test procedure further comprises:
enabling the driver to be tested
disabling the driver to be tested; and
determining whether the tri-state bus is pulled-up such that, if the tri-state bus test is not pulled-up, the driver fails the slow-to-turn-off test.

4. The method of claim 2, wherein the driver speed test procedure further comprises:
enabling the driver to be tested; and
determining whether the tri-state bus is pulled-down such that, if the tri-state bus is not pulled-down, the driver fails the slow-to-turn on test.

5. The method of claim 1, wherein the driver speed test procedure further comprises:
turning off all drivers on the tri-state bus;
setting input values for each of the drivers to be tested to low;
enabling all the drivers to be tested;
enabling pull-up test circuitry on the tri-state bus;
disabling all the drivers to be tested; and
determining whether the tri-state bus is pulled-up.

6. The method of claim 1, wherein the driver static test procedure comprises:
selecting a driver to be tested;
turning off all drivers on the tri-state bus;
enabling pull-up test circuitry on the tri-state bus;
setting an input value to low on the driver to be tested;
setting other drivers on the tri-state bus to high; and
determining whether the tri-state bus is pulled-up such that, if the tri-state bus is not pulled-up, the driver fails the driver stuck-on test.

7. The method of claim 1, wherein the driver static test procedure comprises:
selecting a driver to be tested;
turning off all drivers on the tri-state bus;
enabling the driver to be tested;
setting an input value of the driver to be tested to low;
enabling pull-up test circuitry on the tri-state bus; and
determining whether the tri-state bus is pulled-down such that, if the bus is not pulled-down, the driver fails the driver stuck-off test.

8. A system comprising:
a system for testing tri-state drivers of an integrated circuit, said system being operative to perform a tri-state test including at least one of a driver speed test procedure and a driver static test procedure, the driver speed test procedure including at least one of testing the tri-state bus for an enable line driver slow-to-turn-on condition and an enable line driver slow-to-turn-off condition, the driver static test procedure including at least one of testing the tri-state bus for an enable line driver stuck-on condition and an enable line driver stuck-off condition.

9. The system of claim 8, wherein the driver speed test procedure comprises:
selecting a first driver to be tested;
turning off all drivers on the tri-state bus;
setting an input value to low on the driver to be tested; and
enabling a pull-up test circuit on the tri-state bus.

10. The system of claim 9, wherein the driver speed test procedure further comprises:
enabling the driver to be tested
disabling the driver to be tested; and
determining whether the tri-state bus is pulled-up such that, if the tri-state bus test is not pulled-up, the driver fails the slow-to-turn-off test.

11. The system of claim 9, wherein the driver speed test procedure further comprises:
enabling the driver to be tested; and
determining whether the tri-state bus is pulled-down such that, if the tri-state bus is not pulled-down, the driver fails the slow-to-turn on test.

12. The system of claim 8, wherein the driver speed test procedure further comprises:
turning off all drivers on the tri-state bus;
setting input values for each of the drivers to be tested to low;
enabling all the drivers to be tested;
enabling pull-up test circuitry on the tri-state bus;
disabling all the drivers to be tested; and
determining whether the tri-state bus is pulled-up.

13. The system of claim 8, wherein the driver static test procedure comprises:
selecting a driver to be tested;
turning off all drivers on the tri-state bus;
enabling pull-up test circuitry on the tri-state bus;
setting an input value to low on the driver to be tested;
setting other drivers on the tri-state bus to high; and
determining whether the tri-state bus is pulled-up such that, if the tri-state bus is not pulled-up, the driver fails the driver stuck-on test.

14. The system of claim 8, wherein the driver static test procedure comprises:
selecting a driver to be tested;
turning off all drivers on the tri-state bus;
enabling the driver to be tested;
setting an input value of the driver to be tested to low;
enabling pull-up test circuitry on the tri-state bus; and
determining whether the tri-state bus is pulled-down such that, if the bus is not pulled-down, the driver fails the driver stuck-off test.

15. The system of claim 8, further comprising:
an integrated circuit having a tri-state bus and tri-state bus drivers communicating with said tri-state bus; and
wherein said system for testing said tri-state drivers is communicatively coupled to said integrated circuit.

16. The system of claim 8, further comprising:
an integrated circuit having a tri-state bus and tri-state bus drivers communicating with said tri-state bus; and
wherein said system for testing said tri-state drivers is implemented on said integrated circuit.

17. A system for testing tri-state bus drivers of a tri-state bus in an integrated circuit comprising:
means for selecting a tri-state bus to be tested; and
means for performing a tri-state test including at least one of a driver speed test procedure and a driver static test procedure, the driver speed test procedure including at least one of testing the selected tri-state bus for an enable line driver slow-to-turn-on condition and an enable line driver slow-to-turn-off condition, the driver static test procedure including at least one of testing the selected tri-state bus for an enable line driver stuck-on condition and an enable line driver stuck-off condition.

18. The system of claim 17, further comprising:
means for selecting a first driver to be tested;
means for turning off all drivers on the tri-state bus;
means for setting an input value to low on the driver to be tested; and
means for enabling a pull-up test circuit on the tri-state bus.

19. The system of claim 18, further comprising:
means for enabling the driver to be tested
means for disabling the driver to be tested; and
means for determining whether the tri-state bus is pulled-up such that, if the tri-state bus test is not pulled-up, the driver fails the slow-to-turn-off test.

20. The system of claim 18, further comprising:
means for enabling the driver to be tested; and
means for determining whether the tri-state bus is pulled-down such that, if the tri-state bus is not pulled-down, the driver fails the slow-to-turn on test.

21. The system of claim 17, further comprising:
means for turning off all drivers on the tri-state bus;
means for setting input values for each of the drivers to be tested to low;
means for enabling all the drivers to be tested;
means for enabling pull-up test circuitry on the tri-state bus;
means for disabling all the drivers to be tested; and means for determining whether the tri-state bus is pulled-up.

22. The system of claim 17, further comprising:
means for selecting a driver to be tested;
means for turning off all drivers on the tri-state bus;
means for enabling pull-up test circuitry on the tri-state bus;
means for setting an input value to low on the driver to be tested;
means for setting other drivers on the tri-state bus to high; and
means for determining whether the tri-state bus is pulled-up such that, if the tri-state bus is not pulled-up, the driver fails the driver stuck-on test.

23. The system of claim 17, further comprising:
means for selecting a driver to be tested;
means for turning off all drivers on the tri-state bus;
means for enabling the driver to be tested;
means for setting an input value of the driver to be tested to low;
means for enabling pull-up test circuitry on the tri-state bus; and
means for determining whether the tri-state bus is pulled-down such that, if the bus is not pulled-down, the driver fails the driver stuck-off test.

24. The system of claim 17, further comprising:
means for turning off all drivers on the tri-state bus;
means for enabling pull-up test circuitry on the tri-state bus;
means for setting input values for each of the drivers to low; and
means for determining whether the tri-state bus is pulled-up such that, if the tri-state bus is not pulled-up, the drivers fail the driver stuck-on test.
